(19) United States
(12) Patent Application Publication
(10) Pub. No.: US 2024/0372331 A1
(43) Pub. Date: Nov. 7, 2024

(54) METHOD FOR PRODUCING AT LEAST ONE LASER CHIP, AND LASER CHIP

(71) Applicant: ams-OSRAM International GMBH, Regensburg (DE)

(72) Inventors: Alfred LELL, Maxhutte-Haidhof (DE); Sven GERHARD, Alteglofsheim (DE); Christoph EICHLER, Donaustauf (DE)

(73) Assignee: ams-OSRAM International GmbH, Regensburg (DE)

(21) Appl. No.: 18/686,032

(22) PCT Filed: Aug. 26, 2022
(86) PCT No.: PCT/EP2022/073777

§ 371 Date: Feb. 23, 2024

(30) Foreign Application Priority Data
Aug. 26, 2021 (DE) 102021122145.5

(51) Int. Cl. H01S 5/20

(52) U.S. Cl. CPC H01S 5/2081; H01S 2304/04

(57) ABSTRACT

A method for producing at least one laser chip is specified, the method including the steps of growing a semiconductor layer sequence having an active zone on a substrate, removing part of the substrate, part of the active zone and part of the semiconductor layer sequence by dry-chemical etching, thereby forming at least one side edge extending, at least in places, transversely or perpendicularly to the main plane of extent of the substrate, and removing part of the substrate, part of the active zone and part of the semiconductor layer sequence at the side edge by wet-chemical etching, the active zone being designed to emit laser radiation. A laser chip is additionally specified.

### CROSS-REFERENCE TO RELATED APPLICATIONS

The present application is a national stage entry from International Application No. PCT/EP2022/073777, filed on Aug. 26, 2022, published as International Publication No. WO 2023/025937 A1 on Mar. 2, 2023, and claims priority to German Patent Application No. 10 2021 122 145.5, filed Aug. 26, 2021, the disclosures of all of which are hereby incorporated by reference in their entireties.

### FIELD

A method for producing at least one laser chip and a laser chip are specified.

### BACKGROUND

Laser chips can have a substrate that is at least partially transparent or translucent for electromagnetic radiation emitted in an active zone of the laser chip. This allows at least some of the emitted electromagnetic radiation or scattered light to propagate in the substrate. If electromagnetic radiation that has passed through the substrate to the exit facet of the laser chip is emitted from the exit facet, the beam quality is significantly impaired. For example, imaging errors can occur or the accuracy in processes in which the laser chip is used for material processing, for example, can be reduced.

One object to be achieved is to specify a method for producing at least one laser chip which has improved radiation characteristics. Another object to be achieved is to specify a laser chip which has improved radiation characteristics.

These objects are achieved by the subject-matter of the independent patent claims. Advantageous embodiments and further developments are specified in the dependent claims.

### SUMMARY

According to at least one embodiment of the method for producing at least one laser chip, the method comprises the step of growing a semiconductor layer sequence having an active zone on a substrate. The semiconductor layer sequence can be grown epitaxially on the substrate. The semiconductor layer sequence can comprise at least two layers. For example, the semiconductor layer sequence comprises a first layer which is n-doped and a second layer which is p-doped. The active zone is arranged between the first layer and the second layer. The layers of the semiconductor layer sequence can be arranged one above the other in a stacking direction. The stacking direction runs parallel to the growth direction. The semiconductor layer sequence can comprise at least one semiconductor. For example, the semiconductor layer sequence comprises InGaN. The substrate can comprise GaN, AlN, sapphire or silicon.

According to at least one embodiment of the method for producing at least one laser chip, the method comprises the step of removing a part of the substrate, a part of the active zone and a part of the semiconductor layer sequence by dry-chemical etching, thereby forming at least one side edge which extends, at least in places, transverse or perpendicular to the main extension plane of the substrate.

The part of the substrate, the part of the active zone and the part of the semiconductor layer sequence that are ablated can be ablated in a common dry-chemical etching process. The part of the substrate, the part of the active zone and the part of the semiconductor layer sequence that are ablated are ablated on the side on which the side edge is arranged. The side edge can be arranged on a side on which a radiation exit region is arranged in the finished laser chip. The fact that dry-chemical etching ablates a part of the substrate, a part of the active zone and a part of the semiconductor layer sequence may mean that these parts are removed or at least partially removed. Thus, dry-chemical etching removes or ablates material of the substrate, the active zone and the semiconductor layer sequence. The ablated parts can be regions. Dry-chemical etching can form a cut-out that extends completely through the semiconductor layer sequence and at least partially through the substrate. It is possible that a further part of the substrate, a further part of the active zone and a further part of the semiconductor layer sequence are removed by dry-chemical etching, thereby forming at least one further side edge which extends, at least in places, transverse or perpendicular to the main extension plane of the substrate. The side edge and the further side edge can be arranged on opposite sides of the semiconductor layer sequence.

According to at least one embodiment of the method for producing at least one laser chip, the method comprises the step of ablating a part of the substrate, a part of the active zone and a part of the semiconductor layer sequence at the side edge by wet-chemical etching. The part of the substrate which is ablated by wet-chemical etching is a different part of the substrate than the part which is ablated by dry-chemical etching. Thus, a first part of the substrate is ablated by dry-chemical etching and a second part of the substrate is ablated by wet-chemical etching. The part of the active zone which is ablated by wet-chemical etching is a different part of the active zone than the part which is ablated by dry-chemical etching. Thus, a first part of the active zone is ablated by dry-chemical etching and a second part of the active zone is ablated by wet-chemical etching. The part of the semiconductor layer sequence which is ablated by wet-chemical etching is a different part of the semiconductor layer sequence than the part which is ablated by dry-chemical etching. Thus, a first part of the semiconductor layer sequence is ablated by dry-chemical etching and a second part of the semiconductor layer sequence is ablated by wet-chemical etching. The part of the substrate, the part of the active zone and the part of the semiconductor layer sequence which are ablated by wet-chemical etching are located at the side edge or are adjacent to the side edge. Wet-chemical etching changes the position of the side edge. Wet-chemical etching ablates material, and therefore the side edge is at a different position after wet-chemical etching than after dry-chemical etching and before wet-chemical etching.

The fact that wet-chemical etching ablates a part of the substrate, a part of the active zone and a part of the semiconductor layer sequence may mean that these parts are removed or at least partially removed. Thus, wet-chemical etching removes or ablates material of the substrate, the active zone and the semiconductor layer sequence. The parts can be regions. The cut-out can be enlarged by wet-chemical etching. This can mean that the cut-out has a greater expansion parallel to the main extension plane of the substrate after wet-chemical etching than before wet-chemical etching. It is possible that a further part of the substrate, a further part of the active zone and a further part of the semiconductor layer sequence are removed by wet-chemical etching. This may also change the position of the further side edge.

Wet-chemical etching can be used to form a facet of the laser chip to be produced in the region adjacent to the active zone. After wet-chemical etching, the side edge adjacent to the semiconductor layer sequence and the active zone can extend perpendicular to the main extension plane of the substrate. This means that, after wet-chemical etching, the side edge may have a region, namely the region adjacent to the semiconductor layer sequence and the active zone, which extends perpendicular to the main extension plane of the substrate. In other regions, the side edge may extend transverse to the main extension plane of the substrate after wet-chemical etching.

The substrate can have a crystal structure. A part of the substrate can be ablated by wet-chemical etching until steps have formed on the side edge. The steps can be steps between different crystal planes. A wet-chemical etching process normally proceeds more slowly on a crystal plane or along a crystal plane than between the crystal planes. This means that the wet-chemical etching process can be terminated as soon as the etching process slows down, i.e. less material is ablated per time or the etching rate decreases. In this case, steps have formed on the side edge of the substrate. This means that the substrate is not planar at the side edge but has a certain surface roughness.

It is furthermore possible to terminate the wet-chemical etching process as soon as the side edge adjacent to the semiconductor layer sequence and the active zone has a desired surface roughness. For example, wet-chemical etching can be terminated as soon as the side edge adjacent to the semiconductor layer sequence and the active zone is as smooth or planar as desired. Wet-chemical etching can be terminated before as much material has been ablated from the substrate as has been ablated from the semiconductor layer sequence and the active zone. This means that wet-chemical etching can be terminated as long as the side edge has a step between the semiconductor layer sequence and the substrate. Due to the lower etching rate on the substrate, material of the substrate is ablated more slowly than material of the semiconductor layer sequence during the wet-chemical etching process. This creates the step at the side edge between the semiconductor layer sequence and the substrate.

According to at least one embodiment of the method for producing at least one laser chip, the active zone is designed to emit laser radiation. The active zone may be designed to emit laser radiation during operation of the laser chip. The active zone can have at least one quantum well structure.

The laser chip can be completed by singulating it. This can mean that the substrate is completely cut around a region of the semiconductor layer sequence. This region of the semiconductor layer sequence with the region of the substrate on which this region of the semiconductor layer sequence is arranged then forms the laser chip or at least part of the laser chip. The laser chip can be completed by completely cutting the substrate at least along or parallel to the side edge.

According to at least one embodiment of the method for producing at least one laser chip, the method comprises the steps of growing a semiconductor layer sequence having an active zone on a substrate, ablating a part of the substrate, a part of the active zone and a part of the semiconductor layer sequence by dry-chemical etching, thereby forming at least one side edge which extends, at least in places, transverse or perpendicular to the main extension plane of the substrate, and ablating a part of the substrate, a part of the active zone and a part of the semiconductor layer sequence at the side edge by wet-chemical etching, the active zone being designed to emit laser radiation.

The method described here is based, among other things, on the idea of preventing or reducing the emission of electromagnetic radiation that has been generated in the active zone and that has at least partially propagated in the substrate. The dry-chemical etching process generates an increased surface roughness along the side edge. Dry-chemical etching is carried out in such a way that regions of the substrate, the active zone and the semiconductor layer sequence adjacent to the side edge are roughened. During dry-chemical etching, material is ablated and in regions adjacent to the regions where material is ablated, the structure of the material in these regions is changed by dry-chemical etching. This can mean that material of the substrate, the semiconductor layer sequence and the active zone is damaged or roughened at least in places by dry-chemical etching. In other words, the regions of the substrate, the active zone and the semiconductor layer sequence adjacent to the side edge are roughened by dry-chemical etching.

Further material of the active zone and the semiconductor layer sequence is then ablated in the wet-chemical etching process. After wet-chemical etching, the surface roughness at the side edge adjacent to the semiconductor layer sequence and the active zone is lower than before wet-chemical etching. Thus, wet-chemical etching forms a planar surface at the side edge adjacent to the semiconductor layer sequence and the active zone. At the side edge adjacent to the substrate, the surface roughness is reduced less by wet-chemical etching than at the side edge adjacent to the active zone and the semiconductor layer sequence. This means that the side edge adjacent to the substrate has a rough surface even after wet-chemical etching. During wet-chemical etching, the etching rate at the side edge adjacent to the active zone and the semiconductor layer sequence is greater than at the side edge adjacent to the substrate. This is achieved by the fact that the semiconductor layer sequence on the one hand and the substrate on the other are produced using different production methods. This means that the substrate is produced using a different production method than is used for the semiconductor layer sequence comprising the active zone.

After wet-chemical etching, the side edge adjacent to the substrate has a surface roughness such that electromagnetic radiation or a majority of electromagnetic radiation propagating in the substrate is scattered or absorbed in a region adjacent to the side edge. This means that the electromagnetic radiation or a majority of the electromagnetic radiation propagating in the substrate does not exit the substrate through the side edge. In addition, electromagnetic radiation impinging on the side edge or the region adjacent to the side edge can be reflected back into the active zone. This reduces or prevents the emission of electromagnetic radiation that has propagated in the substrate at a radiation exit side of the laser chip. This prevents a reduction in beam quality and/or imaging errors. The laser chip thus has improved radiation characteristics. In addition, further impairments to the beam quality are avoided, as no changes to the semiconductor layer stack are required that could affect the beam quality. The laser radiation emitted by the laser chip therefore has an increased beam quality. The laser radiation emitted by the laser chip can also have an increased quality of the far field. A high beam quality is particularly important for projection applications or augmented reality or virtual reality applications.

A further advantage is that exactly the region for which shielding is required can be shielded. This means that the entire region of the side edge which is located adjacent to the substrate can have an increased surface roughness. This means that electromagnetic radiation can be prevented from exiting the substrate along the side edge over the entire expansion of the substrate. The increased surface roughness is thus delimited to the exact region in which it is required to prevent or reduce the emission of electromagnetic radiation from the substrate.

According to at least one embodiment of the method, wet-chemical etching is carried out after dry-chemical etching. This means that wet-chemical etching takes place when dry-chemical etching has been completed. This means that material can first be ablated along the side edge during dry-chemical etching and a rough surface can be generated. During wet-chemical etching, a smooth surface of the side edge adjacent to the semiconductor layer sequence and the active zone is advantageously generated. This allows laser radiation generated in the active zone to exit the laser chip adjacent to the active zone. At the same time, the side edge adjacent to the substrate has a higher surface roughness, so that electromagnetic radiation propagating in the substrate is scattered or absorbed in the region of the substrate adjacent to the side edge. This results in improved radiation characteristics.

According to at least one embodiment of the method, the semiconductor layer sequence is grown by metal-organic chemical vapor deposition. The semiconductor layer sequence can be grown epitaxially on the substrate by metal-organic chemical vapor deposition. The advantage of using this production method is that the etching rate for a semiconductor layer sequence produced in this way is higher than for conventional substrates during wet-chemical etching. This advantageously enables a planar radiation exit region of the laser chip to be generated and at the same time the side edge adjacent to the substrate to retain an increased surface roughness.

According to at least one embodiment of the method, the substrate is produced by hydride vapor phase epitaxy. Using this production method has the advantage that for a substrate produced in this way, the etching rate during wet-chemical etching is lower than for conventional semiconductor layer sequences, which are grown, for example, by metal-organic chemical vapor deposition. This advantageously enables a planar radiation exit region of the laser chip to be generated and at the same time the side edge adjacent to the substrate to retain an increased surface accuracy.

According to at least one embodiment of the method, an absorber layer is applied to the substrate at least in places on the side edge. This may mean that the absorber layer is applied to at least some areas of the side edge adjacent to the substrate. The absorber layer can completely cover the substrate along the side edge. The semiconductor layer sequence and the active region can be free of the absorber layer. The absorber layer can be designed to absorb a large part of the electromagnetic radiation impinging on the absorber layer. The absorber layer may have an absorption coefficient of at least 90% or at least 95%. The absorber layer may comprise a metal. For example, the absorber layer comprises at least one of the following metals: Ti, Cr, Al, Ag, Au, Pt, Pd, Ni, W, Ta. The absorber layer can comprise a semiconductor. For example, the absorber layer comprises at least one of the following materials: Si, Ge, GaAs, GaP, InP, InN, SiC, InGaAs, InGaN, InGaP. The absorber layer can comprise a dielectric material. For example, the absorber layer comprises at least one of the following materials: silicon nitride, aluminum oxide, silicon oxide, zinc oxide, tin oxide, wherein the material or materials may have an excess of aluminum or silicon. The absorber layer may comprise carbon and/or a converter.

The absorber layer can advantageously absorb electromagnetic radiation propagating in the substrate. As a result, the electromagnetic radiation propagating in the substrate does not or hardly exits the laser chip on the radiation exit side. This leads to improved radiation characteristics.

According to at least one embodiment of the method, wet-chemical etching is carried out using an alkaline etching solution. For example, wet-chemical etching is carried out using a solution comprising at least one of the following materials: KOH, NaOH, NH₄OH, LiOH, tetramethylammonium hydroxide, N-methyl-2-pyrrolidone. The use of an alkaline etching solution in wet-chemical etching makes it possible to significantly reduce the surface roughness at the side edge adjacent to the semiconductor layer sequence and the active zone by wet-chemical etching. A radiation exit region can be located in this area in the finished laser chip.

Advantageously, the radiation characteristics are improved if the side edge in the area of the radiation exit region is as planar or smooth as possible.

According to at least one embodiment of the method, dry-chemical etching comprises a plasma etching process. High-energy ions may be used in the plasma etching process. For example, at least one of the following materials may be used in the plasma etching process: BCl₃, Cl₂, Ar. By means of a plasma etching process, a sufficiently high surface roughness of the side edge adjacent to the substrate can advantageously be achieved, so that electromagnetic radiation propagating in the substrate can be absorbed or scattered for the most part or completely in the region adjacent to the side edge.

According to at least one embodiment of the method, dry-chemical etching comprises a further plasma etching process different from the plasma etching process. The plasma etching process and the further plasma etching process may differ in the materials used, the temperature, the pressure or the power or in several of these variables. The fact that the plasma etching process and the further plasma etching process are different from each other can mean that the plasma etching process has a different etching rate than the further plasma etching process or that material is ablated at a different angle in the plasma etching process than in the further plasma etching process. Thus, a side edge formed in the plasma etching process can extend at a different angle to the main extension plane of the substrate than a side edge formed in the further plasma etching process. The etching rate in the subsequent wet-chemical etching process may depend on the angle that the side edge forms with respect to the main extension plane of the substrate. Thus, more inclined areas are less easy to smooth, i.e. areas where the side edge is almost perpendicular or perpendicular to the main extension plane of the substrate can be smoothed more easily or have a higher etching rate than areas that extend at a smaller angle to the main extension plane of the substrate. To form the side edge adjacent to the substrate, a plasma etching process can be used, which results in a more inclined side edge than adjacent to the semiconductor layer sequence and the active zone. Thus, the side edge in the region of the substrate is less smoothed during wet-chemical etching and thus has a greater surface roughness after wet-chemical etching than the side edge adjacent to the active zone and the semiconductor layer sequence. This advantageously enables electromagnetic radiation propagating in the substrate to be absorbed or scattered in the substrate in the region adjacent to the side edge.

According to at least one embodiment of the method, the substrate comprises a first region and a second region which are arranged one above the other along a vertical direction, wherein the vertical direction extends perpendicular to the main extension plane of the substrate and more material of the substrate is ablated, by dry-chemical etching, in the first region along a direction parallel to the main extension plane of the substrate than in the second region along a direction parallel to the main extension plane of the substrate. The first region can have a greater expansion parallel to the main extension plane of the substrate than the second region parallel to the main extension plane of the substrate. This is achieved by ablating more material of the substrate in the first region along a direction parallel to the main extension plane of the substrate than in the second area along a direction parallel to the main extension plane of the substrate. This does not automatically mean that more substrate material is ablated in the first region than in the second region. In the first region, the reduction in the expansion of the substrate parallel to the main extension plane of the substrate due to dry-chemical etching is greater than in the second region. The first region may be located between the second region and the semiconductor layer sequence. The different expansions of the first region and the second region parallel to the main extension plane of the substrate enable the laser chip to have a similar expansion in the first region parallel to the main extension plane of the substrate as the semiconductor layer sequence parallel to the main extension plane of the substrate. This can prevent or reduce the emission of electromagnetic radiation from the substrate near a radiation exit region of the laser chip. In addition, the laser chip can have a greater expansion in the second region parallel to the main extension plane of the substrate than in the first region. Adjacent to the second region, a cut-out can be arranged, through which the laser chip can be singulated. Due to the greater expansion of the laser chip in the second region, the tool used for singulating is brought less close to the active zone than in the case where the second region has the same expansion as the first region. The second region can therefore partially serve as a spacer. This prevents damage to the active zone and/or the radiation exit region of the laser chip during singulation. This advantageously prevents damage in the singulation process from leading to poorer performance, efficiency and service life of the laser chip.

According to at least one embodiment of the method, the substrate is completely cut along at least one direction perpendicular to the main extension plane of the substrate. The at least one direction may be parallel to the main extension plane of the substrate and extend along the side edge. The substrate can be cut by sawing. The substrate can be completely cut along different directions. The laser chip can be singulated by cutting. The substrate is advantageously cut by sawing, as the sawing process can increase the surface roughness. In other separation processes, such as scribing or breaking, the surface roughness is increased less. The substrate can therefore have an increased surface roughness on the cut surface or cut surfaces. This advantageously allows electromagnetic radiation propagating in the substrate to be scattered or absorbed at the cut surface or cut surfaces.

According to at least one embodiment of the method, the cutting step comprises sawing using a wedge-shaped saw blade. During the sawing process, at least two sides of the saw blade may extend transverse to the main extension plane of the substrate. As a result, after cutting, at least one region of the side edge adjacent to the substrate extends transverse to the main extension plane of the substrate. As a result, electromagnetic radiation propagating in the substrate can advantageously be scattered and absorbed in the substrate.

According to at least one embodiment of the method, the cutting step comprises laser cutting. If the power of the laser used is sufficiently high, laser cutting can generate areas in the substrate which have increased absorption. This can advantageously prevent or reduce the emission of electromagnetic radiation from the laser chip through the substrate.

According to at least one embodiment of the method, a plurality of side edges is formed by dry-chemical etching, wherein the side edges each extend, at least in places, transverse or perpendicular to the main extension plane of the substrate and the semiconductor layer sequence with the substrate is singulated along the side edges, forming a plurality of laser chips. A plurality of cut-outs can be formed in the semiconductor layer sequence by dry-chemical etching. Two side edges are adjacent to each of the cut-outs. Thus, the cut-outs structure the semiconductor layer sequence, forming a plurality of chip areas of the semiconductor layer sequence, which are arranged spaced apart from each other. A laser chip can be produced from each of the chip areas. The cut-outs can each have the form of a trench or a linear trench. The semiconductor layer sequence can be singulated into a plurality of laser chips along or parallel to the side edges. For this purpose, the substrate can be completely cut along or parallel to the side edges. The substrate can be cut in a vertical direction. This means that, advantageously, a large number of laser chips can be produced simultaneously. This simplifies production and reduces production costs.

Another advantage is that the processes that lead to improved radiation characteristics of the laser chip are self-adjusting. This means that it is not necessary that each of the laser chips be individually adjusted before dry-chemical etching or wet-chemical etching or the application of the absorber layer. This simplifies the production process and leads to a reduction in production costs.

Furthermore, a laser chip is specified. The laser chip is preferably producible by a method described herein. In other words, all features disclosed for the method for producing at least one laser chip are also disclosed for the laser chip and vice versa.

According to at least one embodiment of the laser chip, the laser chip comprises a semiconductor layer sequence having an active zone. The active zone is arranged in the semiconductor layer sequence.

According to at least one embodiment of the laser chip, the laser chip comprises a substrate on which the semiconductor layer sequence is arranged.

According to at least one embodiment of the laser chip, the laser chip comprises at least one side edge which extends, at least in places, transverse or perpendicular to the main extension plane of the substrate and which extends, at least in places, along the substrate and, at least in places, along the semiconductor layer sequence. The side edge can be a side edge of the laser chip. The side edge is therefore directly adjacent to the surroundings of the laser chip. The substrate, the active zone and the semiconductor layer sequence can be directly adjacent to the side edge. Alternatively, the side edge is an inner side edge of the laser chip, the side edge being directly adjacent to the substrate, the active zone and the semiconductor layer sequence and being arranged in the laser chip.

According to at least one embodiment of the laser chip, the active zone is designed to emit laser radiation. The active zone can be designed to emit laser radiation during operation of the laser chip.

According to at least one embodiment of the laser chip, the side edge has at least one step. The step may comprise a region which extends perpendicular or transverse to the main extension plane of the substrate and another region which extends parallel to the main extension plane of the substrate.

According to at least one embodiment of the laser chip, the side edge has a greater surface roughness along the substrate than along the semiconductor layer sequence. This can mean that the side edge adjacent to the substrate has a greater surface accuracy than adjacent to the semiconductor layer sequence.

According to at least one embodiment of the laser chip, the laser chip comprises a semiconductor layer sequence having an active zone, a substrate on which the semiconductor layer sequence is arranged, and at least one side edge which extends, at least in places, transverse or perpendicular to the main extension plane of the substrate and which extends, at least in places, along the substrate and, at least in places, along the semiconductor layer sequence, wherein the active zone is designed to emit laser radiation, the side edge has at least one step, and the side edge has a greater surface roughness along the substrate than along the semiconductor layer sequence.

The laser chip can be produced using the method described here. Thus, the laser chip has the advantages described in connection with the method.

According to at least one embodiment of the laser chip, the side edge has a plurality of steps. The plurality of steps may be arranged adjacent to the substrate.

According to at least one embodiment of the laser chip, the laser chip has a greater expansion in a plane which runs parallel to the main extension plane of the substrate and through the substrate than in a plane which runs parallel to the main extension plane of the substrate and through the semiconductor layer sequence. This can mean that the laser chip has a greater expansion in the region of the substrate or extends over a larger area than in the region of the semiconductor layer sequence. The side edge therefore has at least one step. The step can be arranged adjacent to the semiconductor layer sequence and the substrate. Thus, the substrate can have a greater expansion in the region directly adjacent to the semiconductor layer sequence parallel to the main extension plane of the substrate than the semiconductor layer sequence in the region directly adjacent to the substrate. This enables a mask to be applied to the semiconductor layer sequence and an absorber layer to be applied to the region of the side edge adjacent to the substrate. As the substrate has a greater expansion parallel to the main extension plane of the substrate due to the step, only the substrate is covered by the absorber layer, but not the semiconductor layer sequence. This allows laser radiation to be emitted from a radiation exit region in the active zone during operation of the laser chip. At the same time, emission of electromagnetic radiation from the substrate through the absorber layer is prevented or reduced. This leads to improved radiation characteristics of the laser chip.

According to at least one embodiment of the laser chip, the side edge has a further step. The further step can be arranged adjacent to the substrate. Thus, the substrate comprises a first region and a second region, which are arranged one above the other along the vertical direction. The laser chip has a greater expansion in a plane that runs parallel to the main extension plane of the substrate and through the second region than in a plane that runs parallel to the main extension plane of the substrate and through the first region. This can mean that the laser chip has a greater expansion in the second region or extends over a larger area than in the first region. The second region can serve in part as a spacer. This prevents damage to the radiation exit region during the singulation process.

According to at least one embodiment of the laser chip, an absorber layer is arranged on the substrate at the side edge. The absorber layer can completely cover the substrate at the side edge. The absorber layer can cover the step of the side edge. The absorber layer can cover the further step of the side edge. The absorber layer can advantageously absorb electromagnetic radiation propagating in the substrate. As a result, the electromagnetic radiation propagating in the substrate does not or hardly exits the laser chip on the radiation exit side. This leads to improved radiation characteristics.

In the following, the method described herein for producing at least one laser chip and the laser chip described herein will be explained in more detail in connection with exemplary embodiments and the associated figures.

### BRIEF DESCRIPTION OF THE DRAWINGS

FIGS. 1A and 1B describe an exemplary embodiment of the method for producing at least one laser chip.

FIG. 2 describes a further exemplary embodiment of the method for producing at least one laser chip.

FIGS. 3A and 3B describe a further exemplary embodiment of the method for producing at least one laser chip.

FIGS. 4A and 4B describe a further exemplary embodiment of the method for producing at least one laser chip.

FIGS. 5A and 5B describe a further exemplary embodiment of the method for producing at least one laser chip.

FIGS. 6A and 6B describe a further exemplary embodiment of the method for producing at least one laser chip.

FIGS. 7A and 7B describe a further exemplary embodiment of the method for producing at least one laser chip.

FIG. 8 describes a further exemplary embodiment of the method for producing at least one laser chip.

FIG. 9 shows a laser chip according to an exemplary embodiment.

FIG. 10 shows a laser chip according to a further exemplary embodiment.

### DETAILED DESCRIPTION

Elements that are identical, similar or have the same effect are marked with the same reference signs in the figures. The figures and the proportions of the elements shown in the figures are not to be regarded as being to scale. Rather, individual elements may be shown in exaggerated size for better visualization and/or better comprehensibility.

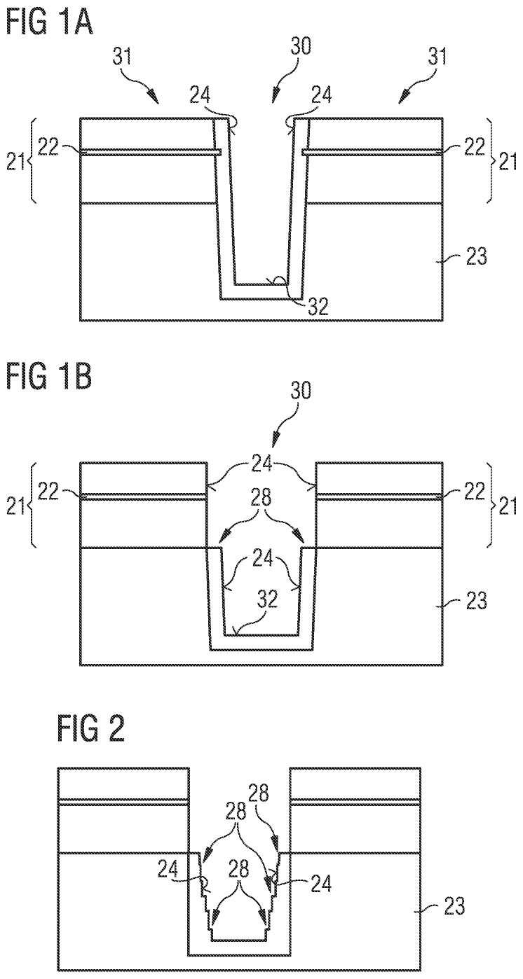

FIGS. 1A and 1B describe an exemplary embodiment of the method for producing at least one laser chip 20. FIG. 1A shows a first method step. A schematic cross-section through a semiconductor layer sequence 21 on a substrate 23 is shown. The semiconductor layer sequence 21 has an active zone 22, which is arranged in the semiconductor layer sequence 21. The active zone 22 is designed to emit laser radiation. The method comprises the step of growing the semiconductor layer sequence 21 on the substrate 23. The semiconductor layer sequence 21 can be grown by metal-organic chemical vapor deposition. The substrate 23 may be prepared by hydride vapor phase epitaxy.

Subsequently, a part of the substrate 23, a part of the active zone 22 and a part of the semiconductor layer sequence 21 are ablated by dry-chemical etching. This generates at least one side edge 24 per laser chip 20 to be produced, said side edge extending, at least in places, transverse or perpendicular to the main extension plane of the substrate 23. FIG. 1A shows two exemplary chip regions 31 of the semiconductor layer sequence 21. A laser chip 20 can be produced from each chip region 31. The two chip regions 31 of the semiconductor layer sequence 21 are generated by generating a cut-out 30 in the semiconductor layer sequence 21 and the substrate 23. This cut-out 30 is generated by the dry-chemical etching. The cut-out 30 extends completely through the semiconductor layer sequence 21 and partially through the substrate 23. During dry-chemical etching, a mask 33 is disposed on the region of the semiconductor layer sequence 21 where no cut-out 30 is formed. The mask 33 may comprise a metal, such as Ni, Ti, Pt or Pd. The mask may additionally or alternatively comprise a dielectric or an oxide, for example SiO₂, Si₃N₄, Al₂O₃, ZrO, ITO, ZnO, Ta₂O₅. The mask 33 is not shown in FIG. 1A.

In total, a plurality of cut-outs 30 can be generated by dry-chemical etching. This means that a plurality of side edges 24 is formed by dry-chemical etching, wherein the side edges 24 each extend, at least in places, transverse or perpendicular to the main extension plane of the substrate 23. As a result, the semiconductor layer sequence 21 can be structured so as to form a plurality of chip regions 31. For example, the chip regions 31 of the semiconductor layer sequence 21 can be arranged at lattice points of a 2-dimensional lattice on the substrate 23. In FIG. 1A, exemplary sections of two chip regions 31 of the semiconductor layer sequence 21 arranged adjacent to each other are shown. A side edge 24 is shown for each of the two chip regions 31.

The material adjacent to the side edge 24 exhibits damage due to dry-chemical etching. In addition, the surface roughness is increased along the side edge 24 compared to other areas of the chip regions 31. The damaged areas are shown in FIG. 1A adjacent to the side edges 24. The material also has damage adjacent to a bottom surface 32 of the cut-out 30.

FIG. 1B shows a next method step. Here, a part of the substrate 23, a part of the active zone 22 and a part of the semiconductor layer sequence 21 at the side edge 24 are ablated by wet-chemical etching. Thus, wet-chemical etching is performed after dry-chemical etching. Wet-chemical etching is carried out using an alkaline etching solution. Since further material is ablated by wet-chemical etching, the cut-out 30 in FIG. 1B is wider than in FIG. 1A. Adjacent to the semiconductor layer sequence 21 and the active zone 22, the etching rate is higher. Wet-chemical etching is carried out until the side edge 24 adjacent to the semiconductor layer sequence 21 and the active zone 22 has a desired low surface roughness. The etching rate is lower adjacent to the substrate 23. Thus, the substrate 23 still has areas of damage adjacent to the side edge 24 and the bottom surface 32 even after wet-chemical etching. In addition, the substrate 23 has a greater expansion parallel to the main extension plane of the substrate 23 than the semiconductor layer sequence 21. Thus, the side edge 24 has a step 28. The step 28 is arranged adjacent to the semiconductor layer sequence 21 and the substrate 23.

To produce the laser chips 20, the semiconductor layer sequence 21 with the substrate 23 is singulated along the side edges 24, forming a plurality of laser chips 20.

FIG. 2 describes a further exemplary embodiment of the method. In contrast to the step shown in FIG. 1B, wet-chemical etching is carried out until the side edge 24 adjacent to the substrate 23 has a plurality of steps 28. The steps 28 may be steps between crystal planes of the substrate 23.

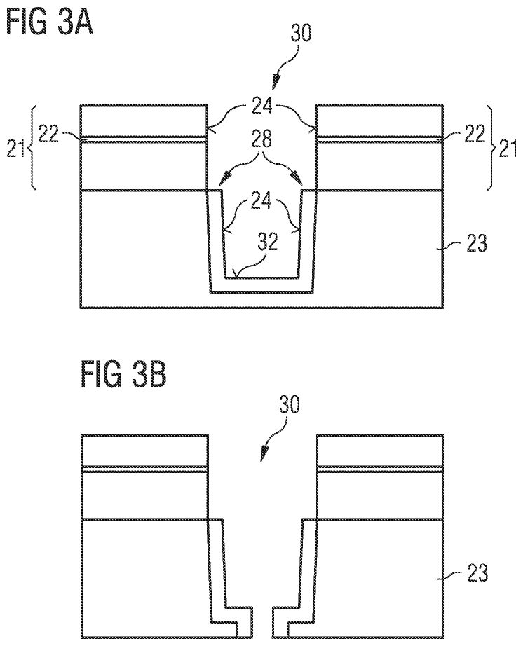

FIGS. 3A and 3B describe a further exemplary embodiment of the method. FIG. 3A shows the step shown in FIG. 1B. Thus, the method steps described in FIGS. 1A and 1B are carried out.

FIG. 3B shows a next method step. In this step, the substrate 23 is completely cut along at least one direction perpendicular to the main extension plane of the substrate 23. The substrate 23 is cut by sawing in the cut-out 30. The sawing increases the surface roughness of the cut areas. Thus, the substrate 23 in FIG. 3B has an increased surface roughness in the lower region adjacent to the cut-out 30. Alternatively, the substrate 23 can be cut by laser cutting.

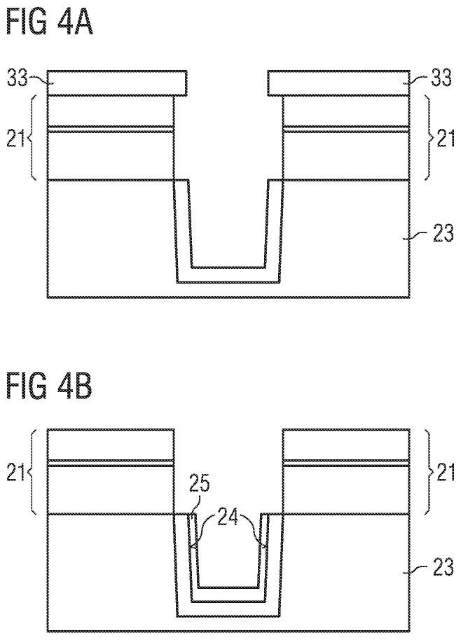

FIGS. 4A and 4B describe a further exemplary embodiment of the method. In FIG. 4A, the step shown in FIG. 1B is shown with the difference that the mask 33, which is arranged on the semiconductor layer sequence 21 during dry-chemical etching, is shown. This means that, according to this exemplary embodiment, the mask 33 remains on the semiconductor layer sequence 21 after dry-chemical etching. The mask 33 protrudes beyond the semiconductor layer sequence 21, but not beyond the substrate 23. The mask 33 protrudes beyond the semiconductor layer sequence 21 in a direction parallel to the main extension plane of the substrate 23. The mask 33 protrudes beyond the semiconductor layer sequence 21 at the side edge 24. Thus, the mask 33 extends beyond the side edge 24 in a direction that is parallel to the main extension plane of the substrate 23.

FIG. 4B shows a further method step. In this step, an absorber layer 25 is applied to the substrate 23 at least in places on the side edge 24. During the application of the absorber layer 25, the mask 33 is still arranged on the semiconductor layer sequence 21. Since the mask 33 protrudes beyond the semiconductor layer sequence 21, the absorber layer 25 is only applied to the substrate 23, but not to the semiconductor layer sequence 21. After the absorber layer 25 has been applied, the mask 33 is removed.

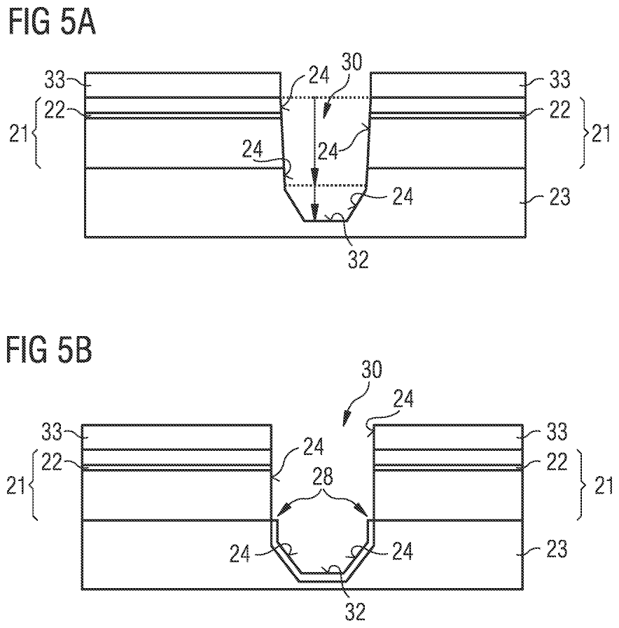

FIGS. 5A and 5B describe a further exemplary embodiment of the method. FIG. 5A shows how, as an alternative to the method shown in FIG. 1A, the cut-out 30 is formed by dry-chemical etching. Here, the mask 33 is arranged on the semiconductor layer sequence 21. The dry-chemical etching comprises a plasma etching process. In this plasma etching process, a part of the semiconductor layer sequence 21, a part of the active zone 22 and a part of the substrate 23 are ablated. Thus, a part of the cut-out 30 is formed. The area between the two dotted lines indicates the area in which material is ablated during the plasma etching process.

The dry-chemical etching comprises a further plasma etching process different from the plasma etching process. In the further plasma etching process, a part of the substrate 23 is ablated. The area between the lower dotted line and the bottom surface 32 of the cut-out 30 indicates the area in which material is ablated during the further plasma etching process. The plasma etching process and the further plasma etching process differ in at least one of their parameters. This ensures that the region of the side edge 24 generated by the plasma etching process has a slope that is different from the slope of the region of the side edge 24 generated by the further plasma etching process. The region of the side edge 24 generated by the plasma etching process may extend at an angle of nearly 90° or 90° to the main extension plane of the substrate 23. The region of the side edge 24 generated by the further plasma etching process may extend at an angle of less than 85° to the main extension plane of the substrate 23. As a result, in the wet-chemical etching process, the regions in which the side edge 24 extends at an angle of less than 85° to the main extension plane of the substrate 23 are smoothed less than the regions of the side edge 24 which extend at an angle of almost 90° or of 90° to the main extension plane of the substrate 23.

FIG. 5B shows a next method step. Wet-chemical etching is carried out as described in FIG. 1B.

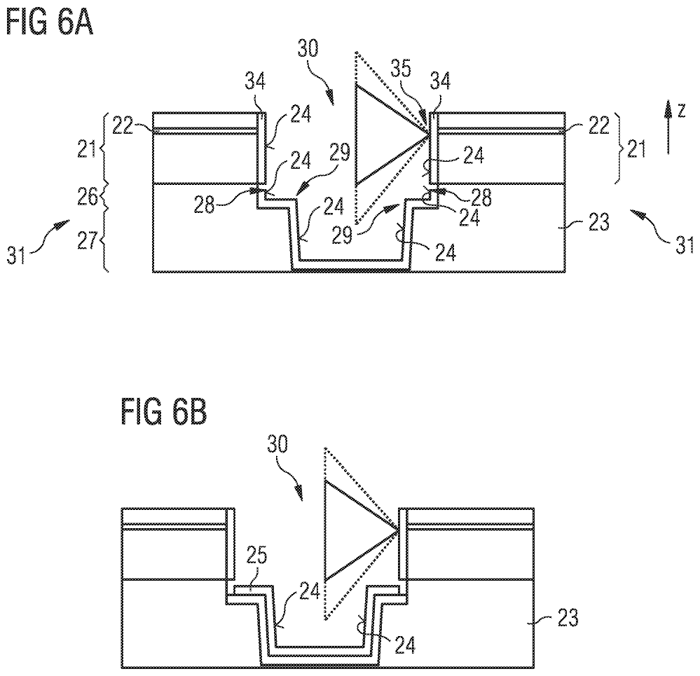

FIGS. 6A and 6B describe a further exemplary embodiment of the method. Here, the method comprises two dry-chemical etching processes. In a first method step, a cut-out 30 is formed in the semiconductor layer sequence 21 and a part of the substrate 23 by dry-chemical etching. In a second method step, a further part of the substrate 23 is removed by dry-chemical etching. Parallel to the main extension plane of the substrate 23, the cut-out 30 in the region of the semiconductor layer sequence 21 and a part of the substrate 23 has a greater expansion than in the region of the substrate 23 in which material is removed during the second method step. The dry-chemical etching process of the first method step may be different from the dry-chemical etching process of the second method step. For example, the dry-chemical etching process of the second method step may be a faster dry-chemical etching process than in the first method step.

After the two dry-chemical etching processes, the substrate 23 comprises a first region 26 and a second region 27, which are arranged one above the other along a vertical direction z. The vertical direction z extends perpendicular to the main extension plane of the substrate 23. In the first region 26, dry-chemical etching ablates more material from the substrate 23 along a direction that is parallel to the main extension plane of the substrate 23 than in the second region 27 along a direction that is parallel to the main extension plane of the substrate 23. Thus, the cut-out 30 has a greater expansion parallel to the main extension plane of the substrate 23 adjacent to the first region 26 than adjacent to the second region 27. A further step 29 is arranged at the side edge 24 adjacent to the first region 26 and the second region 27. This means that between the first region 26 and the second region 27, the further step 29 is arranged at the side edge 24.

After dry-chemical etching, wet-chemical etching is carried out as described, for example, in FIG. 1B. In the process, a step 28 is formed at the side edge 24.

A mirror 34 is arranged for each of the chip regions 31 at the region of the side edge 24 which is adjacent to the semiconductor layer sequence 21 and the active zone 22. Thus, electromagnetic radiation generated in the active zone 22 can exit the completed laser chip 20 through the mirror 34. A radiation exit region 35 of the laser chip 20 can be arranged adjacent to the active zone 22 on the side of the mirror 34 facing the cut-out 30.

FIG. 6B shows a next method step. In this step, an absorber layer 25 is applied to the substrate 23 at least in places on the side edge 24. The absorber layer 25 can completely cover the cut-out 30 in the area of the substrate 23.

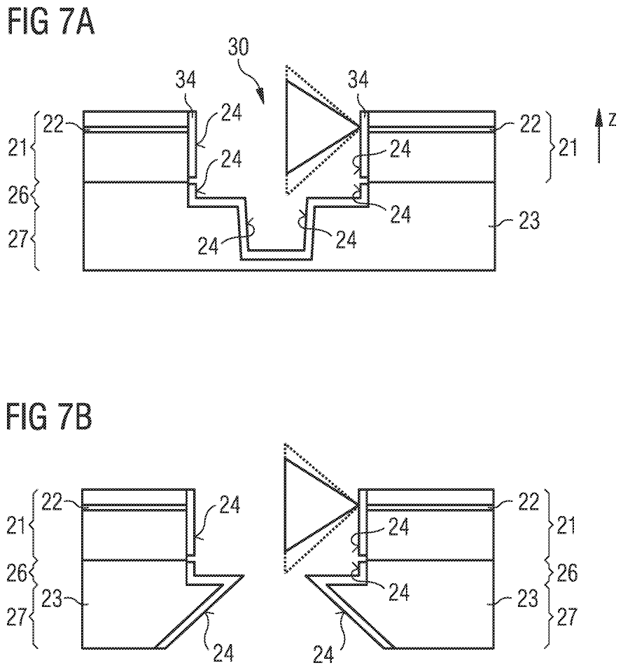

FIGS. 7A and 7B describe a further exemplary embodiment of the method. FIG. 7A shows the method step shown in FIG. 6A. Hence, all the method steps described in FIG. 6A are carried out here.

FIG. 7B shows a next method step. In this step, the substrate 23 is completely cut perpendicular to the main extension plane of the substrate 23. The substrate 23 is cut by sawing using a wedge-shaped saw blade. Therefore, the substrate 23 tapers in the second region 27 away from the first region 26. This means that the substrate 23 has a larger expansion in the second region 27 adjacent to the first region 26 than on the side of the second region 27 facing away from the first region 26. Adjacent to the second region 27, the side edge 24 extends transverse to the main extension plane of the substrate 23. Thus, electromagnetic radiation which strikes the side edge 24 adjacent to the second region 27 can be deflected in the substrate 23, so that the electromagnetic radiation is prevented from exiting the substrate 23. At the transverse side edge 24, impinging electromagnetic radiation can be reflected upwards, i.e. back into the active zone 22.

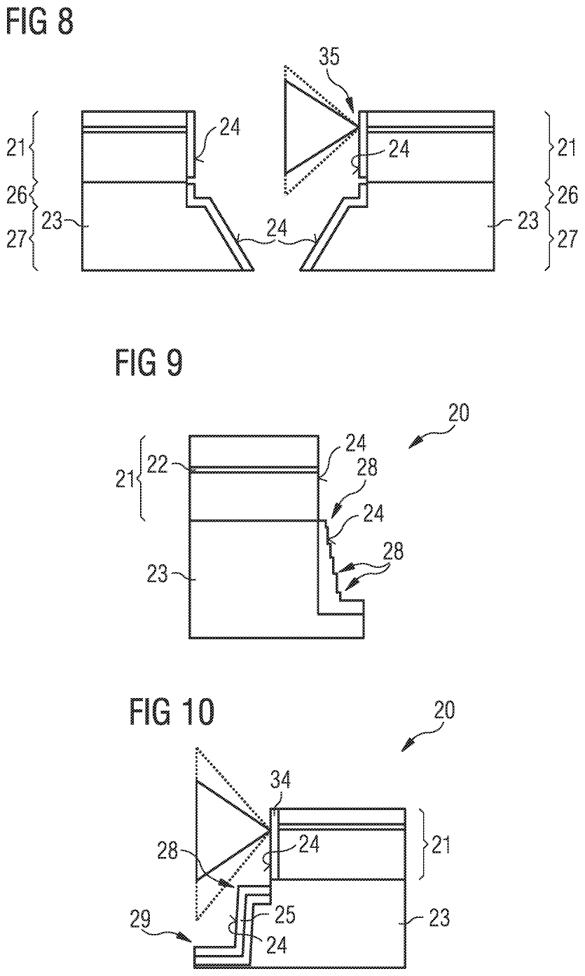

FIG. 8 describes a further exemplary embodiment of the method. First, the steps shown in FIG. 7A are carried out. Then, in contrast to the exemplary embodiment shown in FIG. 7B, the wedge-shaped saw blade is rotated by 180°. In FIG. 7B, the saw blade can be guided towards the substrate 23 from the side of the substrate 23 facing away from the semiconductor layer sequence 21. In FIG. 8, the saw blade can be guided towards the substrate 23 from the semiconductor layer sequence 21. Thus, the second region 27 has a smaller expansion parallel to the main extension plane of the substrate 23 adjacent to the first region 26 than on the side of the second region 27 facing away from the first region 26. At the transverse side edge 24, impinging electromagnetic radiation can be reflected downwards, i.e. away from the radiation exit region 35.

FIG. 9 shows an exemplary embodiment of the laser chip 20. The laser chip 20 comprises the semiconductor layer sequence 21 having the active zone 22 and the substrate 23. The semiconductor layer sequence 21 is arranged on the substrate 23. The laser chip 20 further comprises at least one side edge 24 which extends, at least in places, transverse or perpendicular to the main extension plane of the substrate 23 and which extends, at least in places, along the substrate 23 and, at least in places, along the semiconductor layer sequence 21. The side edge 24 has a plurality of steps 28. The steps 28 may be steps on m-plane surfaces of the crystal of the substrate 23. The side edge 24 has a greater surface roughness along the substrate 23 than along the semiconductor layer sequence 21.

The laser chip 20 has a greater expansion in a plane which runs parallel to the main extension plane of the substrate 23 and through the substrate 23 than in a plane which runs parallel to the main extension plane of the substrate 23 and through the semiconductor layer sequence 21.

FIG. 10 shows a further exemplary embodiment of the laser chip 20. In contrast to the laser chip 20 shown in FIG. 9, the laser chip 20 in FIG. 10 has an absorber layer 25 on the substrate 23 at the side edge 24. In addition, a mirror 34 is arranged at the side edge 24 adjacent to the semiconductor layer sequence 21. In addition to a step 28, the side edge 24 has a further step 29.

The features and exemplary embodiments described in connection with the figures can be combined with one another in accordance with further exemplary embodiments, even if not all combinations are explicitly described. Furthermore, the exemplary embodiments described in connection with the figures may alternatively or additionally have further features as described in the general part.

The invention is not limited to the exemplary embodiments by the description based on the same. Rather, the invention includes any new feature as well as any combination of features, which includes in particular any combination of features in the patent claims, even if this feature or combination itself is not explicitly stated in the patent claims or embodiments.

1. A method for producing at least one laser chip, the method comprising:
growing a semiconductor layer sequence having an active zone on a substrate,
removing a part of the substrate, a part of the active zone and a part of the semiconductor layer sequence by dry-chemical etching, thereby forming at least one side edge which extends, at least in places, transverse or perpendicular to the main extension plane of the substrate, and
removing a part of the substrate, a part of the active zone and a part of the semiconductor layer sequence at the side edge by wet-chemical etching, wherein
the active zone is designed to emit laser radiation, wherein
the dry-chemical etching comprises a plasma etching process, and the dry-chemical etching comprises a further plasma etching process different from the plasma etching process.

2. The method for producing at least one laser chip according to claim 1, wherein wet-chemical etching is carried out after dry-chemical etching.

3. The method for producing at least one laser chip according to claim 1, wherein the semiconductor layer sequence is grown by metal-organic chemical vapor deposition.

4. The method for producing at least one laser chip according to claim 1, wherein the substrate is produced by hydride vapor phase epitaxy.

5. The method for producing at least one laser chip according to claim 1, wherein an absorber layer is applied to the substrate at least in places on the side edge.

6. The method for producing at least one laser chip according to claim 1, wherein wet-chemical etching is carried out using an alkaline etching solution.

7. The method for producing at least one laser chip according to claim 1, wherein the region of the side edge generated by the further plasma etching process extends at an angle of less than 85° to the main extension plane of the substrate.

8. The method for producing at least one laser chip according to claim 7, wherein a mask remains on the semiconductor layer sequence after dry-chemical etching, and the mask protrudes beyond the semiconductor layer sequence, but not beyond the substrate.

9. The method for producing at least one laser chip according to claim 1, wherein the substrate comprises a first region and a second region which are arranged one above the other along a vertical direction, wherein the vertical direction extends perpendicular to the main extension plane of the substrate and more material of the substrate is ablated, by dry-chemical etching, in the first region along a direction parallel to the main extension plane of the substrate than in the second region along a direction parallel to the main extension plane of the substrate.

10. The method for producing at least one laser chip according to claim 1, wherein the substrate is completely cut along at least one direction perpendicular to the main extension plane of the substrate.

11. The method for producing at least one laser chip according to claim 10, wherein the cutting step comprises sawing using a wedge-shaped saw blade.

12. The method for producing at least one laser chip according to claim 10, wherein the cutting step comprises laser cutting.

13. The method for producing at least one laser chip according to claim 1, wherein a plurality of side edges is formed by dry-chemical etching, wherein the side edges each extend, at least in places, transverse or perpendicular to the main extension plane of the substrate and the semiconductor layer sequence with the substrate is singulated along the side edges, forming a plurality of laser chips.

14. A laser chip comprising:
a semiconductor layer sequence having an active zone,
a substrate on which the semiconductor layer sequence is arranged, and
at least one side edge which extends, at least in places, transverse or perpendicular to the main extension plane of the substrate and which extends, at least in places, along the substrate and, at least in places, along the semiconductor layer sequence, wherein
the active zone is designed to emit laser radiation,
the side edge has at least one step, and
the side edge has a greater surface roughness along the substrate than along the semiconductor layer sequence, wherein
the side edge is formed by dry-chemical etching, the dry-chemical etching comprises a plasma etching process, and the dry-chemical etching comprises a further plasma etching process different from the plasma etching process.

15. The laser chip according to claim 14, wherein the laser chip has a greater expansion in a plane which runs parallel to the main extension plane of the substrate and through the substrate than in a plane which runs parallel to the main extension plane of the substrate and through the semiconductor layer sequence.

16. The laser chip according to claim 14, wherein the side edge has a further step.

17. The laser chip according to claim 14, wherein an absorber layer is arranged on the substrate at the side edge.

18. A laser chip comprising:
a semiconductor layer sequence having an active zone,
a substrate on which the semiconductor layer sequence is arranged, and
at least one side edge which extends, at least in places, transverse or perpendicular to the main extension plane of the substrate and which extends, at least in places, along the substrate and, at least in places, along the semiconductor layer sequence, wherein
the active zone is designed to emit laser radiation,
the side edge has at least one step, and
the side edge has a greater surface roughness along the substrate than along the semiconductor layer sequence, wherein
an absorber layer is arranged on the substrate at the side edge.
